(19) United States
(12) Patent Application Publication
(10) Pub. No.: US 2026/0344244 A1
(43) Pub. Date: Oct. 29, 2026

(54) Display Device

(71) Applicant: LG Display Co., Ltd., Seoul (KR)

(72) Inventors: SeungHan Paek, Seoul (KR); Chul Nam, Seoul (KR); Kyungjae Yoon, Seoul (KR); Jeonphill Han, Goyang-si (KR); Sinchul Kang, Gimpo-si (KR)

(21) Appl. No.: 19/575,669

(22) Filed: Mar. 23, 2026

(30) Foreign Application Priority Data
Apr. 29, 2025 (KR) 10-2025-0056645

(51) Int. Cl. H10K 59/80

(52) U.S. Cl. CPC H10K 59/80

(57) ABSTRACT

A display device according to one or more embodiments of the present disclosure includes a display panel including a folding area, a bending area, a first non-folding area, a second non-folding area, and a third non-folding area. A bottom plate is disposed on a rear surface of the display panel, and a folding auxiliary layer is disposed on a rear surface of the bottom plate. The bottom plate includes a plurality of patterns overlapping the folding area. The folding auxiliary layer overlaps the entire folding area and overlaps a part of each of the first non-folding area and the second non-folding area disposed with the folding area therebetween, thereby preventing wrinkles from occurring in the folding area and deterioration in visibility.

### CROSS-REFERENCE TO RELATED APPLICATION

This application claims priority to Republic of Korea Patent Application No. 10-2025-0056645, filed on Apr. 29, 2025, which is incorporated herein by reference in its entirety.

### TECHNICAL FIELD

The present disclosure relates to a display device, and more particularly, for example, without limitation, to a display device with a reduced thickness and improved visibility.

### BACKGROUND

In recent years, as society has entered a full-fledged information era, the field of display that processes and displays a large amount of information has rapidly developed. Display devices used for a monitor of a computer, a TV, or a mobile phone include an organic light emitting display (OLED) that emits light by itself, and a liquid crystal display (LCD) that requires a separate light source, etc.

Display devices have been applied in a variety of applications, including computer monitors and TVs as well as personal portable devices, etc., and research is being conducted on display devices that have a large display area and have a reduced volume and weight.

In particular, in recent years, a flexible display device manufactured to display images even when bent or folded like paper is attracting attention as a next-generation display device. The flexible display device may be classified into an unbreakable display device having high durability by utilizing a plastic thin film transistor substrate other than glass, a bendable display device which may be bent without breaking, a rollable display device which may be rolled, and a foldable display device which may be folded. Such a flexible display device has advantages in space utilization, interior, and design, and may have various application fields.

The description provided in the background section should not be assumed to be prior art merely because it is mentioned in or associated with the background section. The background section may include information that describes one or more embodiments of the subject technology.

### SUMMARY

On the other hand, the inventors of the present application found that, there is a problem in that the shrinkage of the display panel does not proceed smoothly, wrinkles occur, or damage occurs due to the shrinkage deformation generated in the structure supporting the shape of the display panel in the folding area, thereby deteriorating the display quality of the display panel.

An object to be achieved by the present disclosure is to provide a display device capable of preventing a phenomenon in which a wrinkle occurs in a folding area and visibility decreases.

An object to be achieved by the present disclosure is to provide a display device having a structure capable of reducing a thickness and a weight of a foldable display device.

According to one or more embodiments of the present disclosure, a display device includes a display panel including a folding area, a bending area, a first non-folding area, a second non-folding area, and a third non-folding area, a bottom plate disposed on a rear surface of the display panel, and a folding auxiliary layer disposed on a rear surface of the bottom plate, the bottom plate includes a plurality of patterns overlapping the folding area, the folding auxiliary layer overlaps the entire folding area, and overlaps a portion of each of the first non-folding area and the second non-folding area disposed with the folding area therebetween.

Other detailed matters of the embodiments are included in the detailed description and the drawings.

According to one or more embodiments of the present disclosure, in the folding area, the bottom plate has a plurality of patterns and the folding auxiliary layer is disposed under the bottom plate to prevent wrinkles from occurring even when the display device is repeatedly folded.

According to one or more embodiments of the present disclosure, the bottom plate is made of non-alkali glass as a single layer, and the substrate of the display panel disposed on the bottom plate is made of a single layer, thereby reducing the thickness and weight of the display device.

According to one or more embodiments of the present disclosure, by including a folding auxiliary layer overlapping the plurality of patterns of the bottom plate, moisture and foreign substances introduced from the plurality of patterns are blocked to prevent the life of the display device from being shortened, thereby implementing a low-power display device.

The effects according to the present disclosure are not limited to the contents exemplified above, and more various effects are included in the present disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other embodiments, features and other advantages of the present disclosure will be more clearly understood from the following detailed description taken in conjunction with the accompanying drawings, in which:

FIG. 1 is a schematic plan view of a display device according to one or more embodiments of the present disclosure.

FIG. 2 is a schematic plan view of a partial area of a display device according to one or more embodiments of the present disclosure.

FIG. 3 is a cross-sectional view taken along line A-B of FIG. 1.

FIG. 4 is a view schematically illustrating a state in which a display device is bent in a bending area according to one or more embodiments of the present disclosure.

FIG. 5 is a cross-sectional view taken along line C-D of FIG. 1.

FIG. 6 is a view illustrating a plurality of patterns provided in the bottom plate in the folding area.

FIG. 7 is a view illustrating a plurality of patterns provided on a bottom plate in a folding area of a display device according to one or more other embodiments of the present disclosure.

FIG. 8 is a view illustrating a state in which a bottom plate of the display device is folded around a folding axis according to one or more embodiments of the present disclosure.

FIG. 9 is a view illustrating a shape of edges of a plurality of patterns in an edge area of a bottom plate in a folding area of a bottom plate of a display device according to one or more embodiments of the present disclosure.

FIGS. 10A and 10B are images of the shape of the edge area of the bottom plate.

FIG. 11 is a cross-sectional view illustrating a part of a display area located in a folding area of a display device according to one or more embodiments of the present disclosure.

FIG. 12 is a cross-sectional view illustrating a part of a display area located in a folding area of a display device according to one or more embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the disclosure and may be thus different from those used in actual products.

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.) ratios, angles, numbers, and the like illustrated in the accompanying drawings for describing the embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” “comprising,” and “consist of” used herein are generally intended to allow other components to be added unless the terms are used with the term “only”. Any references to singular may include plural unless expressly stated otherwise.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

In describing a time relationship, for example, when the temporal order is described as, for example, “after,” “subsequent,” “next,” and “before,” a case which is not continuous may be included unless a more limiting term, such as “just,” “immediate(ly),” or “direct(ly)” is used.

When an element or layer is disposed “on” another element or layer, another layer or another element may be interposed directly on the other element or therebetween.

The terms, such as “below,” “lower,” “above,” “upper” and the like, may be used herein to describe a relationship between element(s) as illustrated in the drawings. It will be understood that the terms are spatially relative and based on the orientation depicted in the drawings.

Although the terms “first”, “second”, “A,” “B,” “(a),” and “(b),” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, the present disclosure will be described in detail with reference to the drawings.

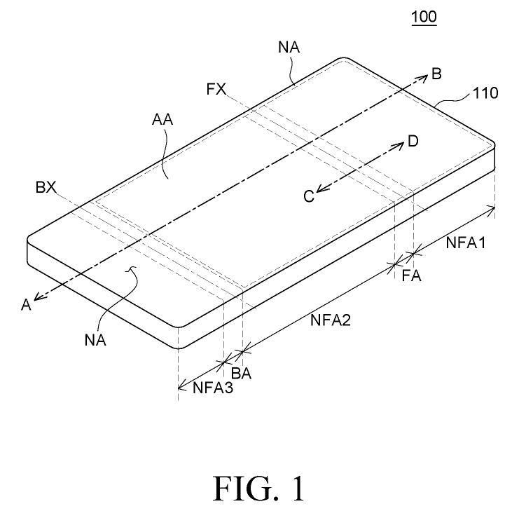

FIG. 1 is a schematic plan view of a display device according to one or more embodiments of the present disclosure.

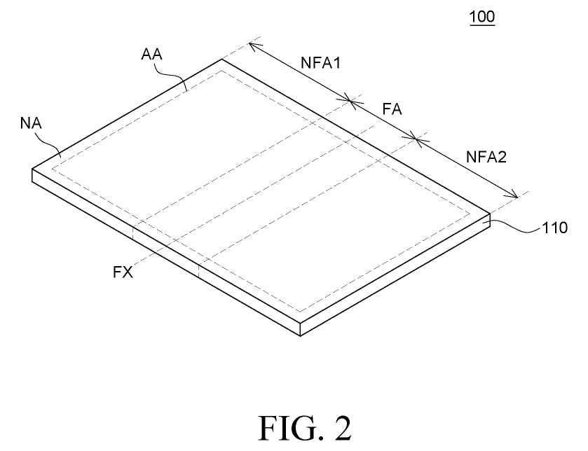

FIG. 2 is a schematic plan view of a partial area of a display device according to one or more embodiments of the present disclosure.

Referring to FIGS. 1 and 2, a display device 100 according to one or more embodiments of the present disclosure is a device for displaying a video or a still image. The display device 100 may be used as a display screen for various products such as television, laptop, monitor, billboard, and Internet of Things, as well as a portable electronic device such as a mobile phone, a smart phone, a tablet PC, a watch phone, a mobile communication terminal, an electronic notebook, an electronic book, PMP, navigation, and UMPC. Embodiments are not limited thereto. As an example, the display device 100 may be also used as a display screen for a building, a vehicle, household appliances, etc. without being limited thereto.

As an example, the display device 100 may include at least one folding area FA, a plurality of non-folding areas NFA1, NFA2, NFA3, and/or at least one bending area BA, without being limited thereto.

For example, the display device 100 may include a folding area FA, a first non-folding area NFA1, a second non-folding area NFA2, a third non-folding area NFA3, and a bending area BA. However, the present disclosure is not limited thereto, and the display device 100 may include two or more folding areas FA and two or more bending areas BA. As an example, at least one of the folding area FA, the first non-folding area NFA1, the second non-folding area NFA2, the third non-folding area NFA3, and the bending area BA may be omitted, depending on the design.

The folding area FA of the display device 100 may mean an area that may be folded around the folding axis FX. The bending area BA of the display device 100 may mean an area that may be bent about the bending axis BX. As an example, the radius of curvature of the folding area FA of the display device 100 may be smaller than the radius of curvature of the bending area BA, without being limited thereto. As an example, the radius of curvature of the folding area FA of the display device 100 in a folded state may be smaller than the radius of curvature of the bending area BA in a bent state, without bring limited thereto.

In addition, as an example, the folding area FA of the display device 100 may include the display area AA, but the bending area BA may not include the display area AA, without being limited thereto.

The first non-folding area NFA1, the second non-folding area NFA2, and the third non-folding area NFA3 may be flat portions that are not folded.

The folding area FA1 may be disposed between the first non-folding area NFA1 and the second non-folding area NFA2. A bending area BA may be disposed between the second non-folding area NFA2 and the third non-folding area NFA3.

The folding area FA and the bending area BA may be disposed to be spaced apart from each other with at least one non-folding area NFA interposed therebetween. For example, the folding area FA and the bending area BA may be disposed to be spaced apart from each other with the second non-folding area NFA interposed therebetween. As an example, the folding area FA and the bending area BA may be disposed to be parallel to each other, without being limited thereto. As an example, the folding area FA and the bending area BA may be disposed to be spaced apart from each other in a direction perpendicular to the folding area FA, without being limited thereto.

The display device 100 according to one or more embodiments of the present disclosure may include a display panel 110.

The display panel 110 may include a folding area FA, a first non-folding area NFA1, a second non-folding area NFA2, a third non-folding area NFA3, and a bending area BA.

Further, the display panel 110 may include a display area AA and a non-display area NA.

Each of the display area AA and the non-display area NA of the display panel 110 may be disposed in a part of the folding area FA, a part of the first non-folding area NFA1, and a part of the second non-folding area NFA2.

At least a part of the non-display area NA of the display panel 110 may be disposed to surround the display area AA disposed in a part of the folding area FA, a part of the first non-folding area NFA1, and a part of the second non-folding area NFA2.

As an example, each of the bending area BA and the third non-folding area NFA3 of the display panel 110 may be a non-display area NA, without being limited thereto. As an example, the display area AA may be further disposed in at least one of the bending area BA and the third non-folding area NFA3, without being limited thereto.

The folding area FA of the display panel 110 may include the display area AA, and the bending area BA of the display panel 110 may not include the display area AA.

The display panel 110 displays an image through the display area AA. The non-display area NA does not display an image. In the non-display area NA, a driving unit and/or lines for driving the display area AA may be disposed.

The display panel 110 may be of various types, such as a display panel including an organic light emitting element OLED, a display panel including a light emitting element LED, a display panel including a micro light emitting element micro-LED and a liquid crystal display panel, etc., without being limited thereto. Hereinafter, for convenience of description, a display panel including a light emitting element will be mainly described as an example.

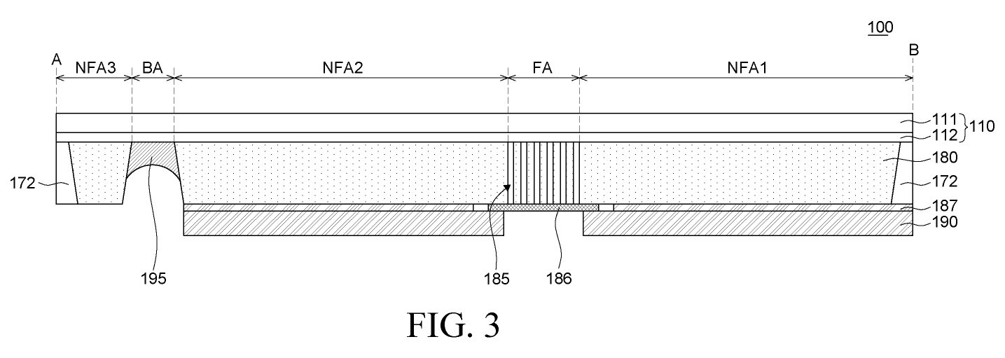

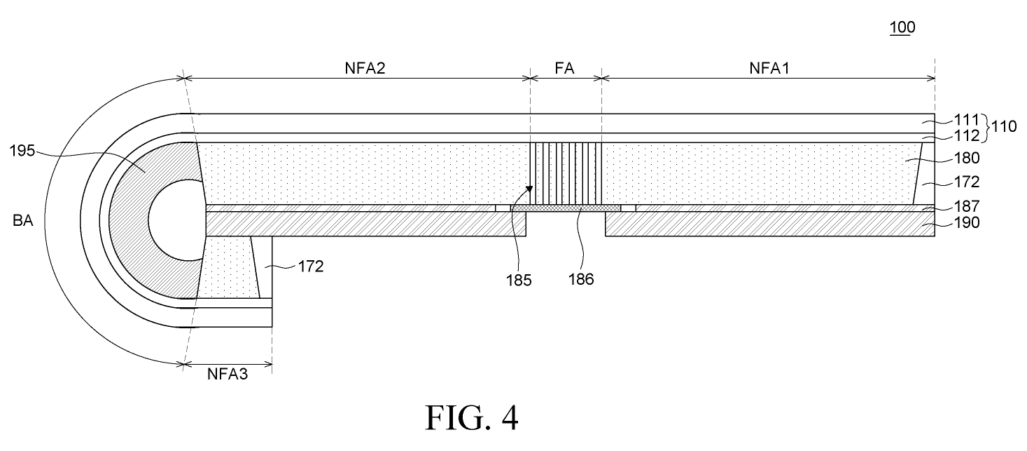

Next, a structure of a display device according to one or more embodiments of the present disclosure will be described in detail with reference to FIGS. 3 and 4.

FIG. 3 is a cross-sectional view taken along line A-B of FIG. 1.

FIG. 4 is a view schematically illustrating a state in which a display device is bent in a bending area according to one or more embodiments of the present disclosure.

Referring to FIGS. 3 and 4, a display device 100 according to one or more embodiments of the present disclosure may include a display panel 110, a bottom plate 180, and a folding auxiliary layer 186.

The display panel 110 may include a substrate 112 and a display element layer 111 disposed on the substrate 112.

The substrate 112 may include a material capable of bending and folding. For example, the substrate 112 may include at least one of polyimide (PI), polydimethylsiloxane (PDMS), polyurethane (PU), and polytetrafluoroethylene (PTFE), without being limited thereto.

The substrate 112 may be formed of a single layer. The substrate 112 may be formed of 1 μm to 16 μm. Embodiments are not limited thereto. As an example, the substrate 112 may be formed of a multiple-layer. As an example, the substrate 112 may be formed of less than 1 μm or greater than 16 μm, without being limited thereto.

As described above, since the substrate 112 is formed as a single layer, the structure of the display device 100 may be simplified and the thickness of the display device 100 is reduced, such that the stress applied to the display device 100 due to the folding or bending of the display device 100 may be reduced, thereby suppressing the defect of the display device 100.

Although not illustrated in the drawings, the display element layer 111 may include a plurality of light emitting devices, a plurality of transistors, and a plurality of link lines.

Some of the plurality of link lines included in the display element layer 111 may be disposed to extend from the non-display area NA disposed in each of the folding area FA, the first non-folding area NFA1, and the second non-folding area NFA2 to the bending area BA and the second non-folding area NFA3.

A bottom plate 180 may be disposed on a part of the rear surface of the substrate 112.

As an example, the bottom plate 180 may be formed of glass, without being limited thereto. For example, the bottom plate 180 may be a non-alkaline glass.

Specifically, the bottom plate 180 may include an alkali-free material. For example, the bottom plate 180 may include silica (SiO2).

Accordingly, the bottom plate 180 has excellent chemical durability, and may have a characteristic that degeneration does not occur even with high temperature and rapid temperature changes. Embodiments are not limited thereto. As an example, the bottom plate 180 may include a material other than glass, such as plastic, ceramics, oxide, metal, etc., without being limited thereto.

Further, the bottom plate 180 may not include an alkali metal. Accordingly, the ion exchange process is not utilized in the process of forming the bottom plate 180.

In order to form a glass including an alkali metal, an ion exchange process is required, and the glass formed through the ion exchange process greatly reduces the strength of the edge or cut surface, so that durability may be deteriorated.

Specifically, in order to form a glass containing an alkali metal, soda-lime glass containing sodium (Na) ions is immersed in an alkali metal salt solution (for example, a potassium nitrate) solution).

Thereafter, the alkali metal salt solution is melted at a high temperature of 400 to 500°C to remove sodium (Na) ions inside the soda-lime glass, and potassium (Ka) ions larger than sodium (Na) ions are positioned in the sodium (Na) ion site inside the soda-lime glass to exchange ions.

When potassium (Ka) ions, which are larger than sodium (Na) ions, are located inside the glass, compressive stress is generated on the glass surface due to the difference in ion size.

When such ion exchange is completed, the glass is gradually cooled and a compressive stress layer may be formed on the glass surface.

However, during this process, a compressive stress layer may not be formed on the edge of the glass and the cutting surface. In this case, the chemical and physical durability of the edge of the glass and the cutting surface is deteriorated.

Since the ion exchange process uses an alkali metal salt solution, there is a problem that the process becomes more difficult as the thickness of the glass increases, and there is a problem that causes environmental pollution.

On the other hand, the bottom plate 180 of the display device 100 according to one or more embodiments of the present disclosure does not include an alkali metal, so that there is no need to use an ion exchange process for enhancing durability.

Therefore, even though the bottom plate 180 which does not include an alkali metal becomes thicker than the glass which includes an alkali metal, uniform chemical and physical durability may be ensured, and environmental pollution may not be generated even in the process of forming the bottom plate 180.

Since the substrate 112 of the display device 100 according to one or more embodiments of the present disclosure has a single-layered structure, it is desired for the bottom plate 180 disposed on the rear surface of the substrate 112 to stably support the substrate 112.

Since the bottom plate 180 is a non-alkali glass, the chemical and physical durability of the entire surface including the edge and the cut surface of the bottom plate 180 may be ensured even though the bottom plate 180 has a thickness enough to stably support the substrate 112.

For example, the thickness of the bottom plate 180 may be 1 μm to 200 μm, and specifically, the thickness of the bottom plate 180 may be 50 μm to 200 μm, without being limited thereto.

When the thickness of the bottom plate 180 is less than 50 μm, defects such as sagging of the bottom plate 180, which serves to support the display panel 110, may occur in some areas.

When the thickness of the bottom plate 180 exceeds 200 μm, when the display device 100 is folded in the folding area FA, wrinkles may occur in the display device 100 due to an increase in thickness, a problem in which a step is visually recognized in an area where wrinkles occur, and a problem in which the weight of the display device 100 increases may occur.

The bottom plate 180 of the display device 100 according to one or more embodiments of the present disclosure is formed of non-alkali glass to easily implement a thickness exceeding 50 μm. In addition, since the bottom plate 180 has a thickness of less than 200 μm, it is possible to reduce or prevent wrinkles of the display device 100 in the folding area FA or a defect in which a step is visually recognized.

The bottom plate 180 may be disposed in at least a portion of any or each of the folding area FA, the first non-folding area NFA1, the second non-folding area NFA2, and the third non-folding area NFA3 of the display device 100.

Accordingly, in the folding area FA, the first non-folding area NFA1, the second non-folding area NFA2, and the third non-folding area NFA3 of the display device 100, the bottom plate 180 may stably support the display panel 110. Embodiments are not limited thereto. As an example, the bottom plate 180 may be omitted in at least a portion of any of the folding area FA, the first non-folding area NFA1, the second non-folding area NFA2, and the third non-folding area NFA3 of the display device 100.

As an example, the bottom plate 180 may include a plurality of patterns 185 in the folding area FA of the display device 100, without being limited thereto.

The plurality of patterns 185 may be disposed to be spaced apart from each other in the folding area FA of the display device 100. As an example, the plurality of patterns 185 may be disposed to be spaced apart from each other in a folding direction in the folding area FA of the display device 100, without being limited thereto.

The plurality of patterns 185 may serve to facilitate folding of the display device 100 when the display device 100 is folded in the folding area FA and to relieve stress applied to the bottom plate 180 during folding.

In the bending area BA of the display device 100, as an example, the first micro coating layer 195 may be disposed on the rear surface of the display panel 110, without being limited thereto.

The first micro coating layer 195 may be filled in the hole of the bottom plate 180 provided in the bending area BA.

The first micro coating layer 195 may be disposed on the rear surface of the display panel 110 and serve to suppress the occurrence of cracks in the display panel 110 in the bending area BA and adjust the neutral surface of the bending area BA.

As shown in FIG. 4, the display device 100 may be bent in the bending area BA.

When the display device 100 is bent, the third non-folding area NFA3 may be located on the rear surface of the second non-folding area NFA2.

Referring to FIGS. 3 and 4, in a part of each of the first non-folding area NFA1 and the third non-folding area NFA3 of the display device 100, the sealing layer 172 may be disposed on the rear surface of the display panel 110.

As an example, the sealing layer 172 may be disposed at an edge of the first non-folding area NFA1 and an edge of the third non-folding area NFA3. As an example, the sealing layer 172 may be disposed at an edge of the first non-folding area NFA1 and an edge of the third non-folding area NFA3 facing outside of the display panel 110, without being limited thereto.

Further, the sealing layer 172 may be disposed on the rear surface of the substrate 112 in an area in which the bottom plate 180 is not disposed in each of the first non-folding area NFA1 and the third non-folding area NFA3.

As an example, the sealing layer 172 may serve to fill a step generated between the substrate 112 and the bottom plate 180, without being limited thereto.

As an example, a folding auxiliary layer 186 may be disposed on a part of the rear surface of the bottom plate 180, without being limited thereto.

As an example, the folding auxiliary layer 186 may overlap the entire folding area FA of the display device 100.

In addition, as an example, the folding auxiliary layer 186 may be disposed to extend to a part of the first non-folding area NFA1 and a part of the second non-folding area NFA2, without being limited thereto.

As an example, the folding auxiliary layer 186 may overlap a part of the display area AA of each of the first non-folding area NFA1 and the second non-folding areas NFA2. For example, the display area AA may include an emission area and a non-emission area, and the folding auxiliary layer 186 may overlap a part of the emission area and a part of the non-emission area of each of the first non-folding area NFA1 and the second non-folding areas NFA2.

The folding auxiliary layer 186 may serve to reduce or prevent damage that may occur during a process of repeatedly folding or unfolding the display device 100.

Specifically, the folding auxiliary layer 186 may absorb the mechanical stress generated when the display device 100 is folded or unfolded, thereby reducing the impact applied to the display device 100, and in particular, may reduce or prevent wrinkles or damage that may occur in the folding area FA of the display device 100.

In addition, the folding auxiliary layer 186 may be disposed on the rear surface of the bottom plate 180 and disposed to overlap the entire plurality of patterns 185 provided in the bottom plate 180.

Accordingly, it may serve to reduce or prevent moisture or foreign substances from being introduced through the plurality of patterns 185. Specifically, moisture or foreign substances are introduced through the plurality of patterns 185 and moisture or foreign substances move to the display panel 110 to suppress the lifespan of the plurality of light emitting devices disposed on the display panel 110.

In addition, as an example, the folding auxiliary layer 186 may be a flexible silicon-based adhesive or an adhesive film, without being limited thereto. Accordingly, it is attached to the rear surface of the bottom plate 180 without a separate adhesive layer, and at the same time, the adhesive force is maintained even after repeated folding and unfolding, and the display device 100 may have flexibility that does not interfere with the folding and unfolding of the display device 100. Embodiments are not limited thereto. As an example, the folding auxiliary layer 186 may not have adhesiveness, and may be attached to the rear surface of the bottom plate 180 with a separate adhesive layer.

The folding auxiliary layer 186 may have a thickness of 1 μm to 25 μm, without being limited thereto.

When the thickness of the folding auxiliary layer 186 is less than 1 μm, moisture or foreign substances may penetrate into the plurality of patterns 185, or a crack may occur in the folding auxiliary layer 186 due to repeated folding and unfolding. In addition, when the thickness of the folding auxiliary layer 186 exceeds 25 μm, flexibility may decrease.

In addition, the bottom plate 180 may not be disposed in the bending area BA of the display device 100. Accordingly, when the display device 100 is bent in the bending area BA, the display device 100 may be easily bent without interference from the bottom plate 180.

As an example, the heat dissipation sheet 190 may be disposed on a part of the rear surface of the bottom plate 180, without being limited thereto.

As an example, the heat dissipation sheet 190 may be attached to the rear surface of the bottom plate 180 by the first adhesive layer 187. Embodiments are not limited thereto. As an example, the heat dissipation sheet 190 may have adhesiveness, and may be attached to the rear surface of the bottom plate 180 without the first adhesive layer 187. As an example, heat dissipation sheet 190 may be omitted depending on the design. As an example, the heat dissipation sheet 190 may be attached to the rear surface of the bottom plate 180 exposed by the folding auxiliary layer 186. As an example, the heat dissipation sheet 190 may be further attached to a rear surface of a part of the folding auxiliary layer 186, without being limited thereto. As an example, the heat dissipation sheet 190 may be extended beyond the first adhesive layer 187 onto a part of the folding auxiliary layer 186 outside the folding area FA, without being limited thereto.

The heat dissipation sheet 190 may serve to reduce or prevent a defect from occurring on the display device 100 due to heat generated when the display device 100 is driven.

FIGS. 3 and 4 illustrate a structure in which the heat dissipation sheet 190 is a single layer. However, the structure of the heat dissipation sheet 190 of the display device 100 according to one or more embodiments of the present disclosure is not limited thereto. For example, the heat dissipation sheet 190 may have a multilayer structure including two or more layers.

Referring to FIG. 3, when the display device 100 is not bent in the bending area BA, the first adhesive layer 187 and the heat dissipation sheet 190 may be disposed to overlap at least a portion of each of the first non-folding area NFA1 and the second non-folding area NFA2.

Further, referring to FIG. 4, when the display device 100 is bent in the bending area BA, the first adhesive layer 187 and the heat dissipation sheet 190 may overlap at least a part of each of the first non-folding area NFA1, the second non-folding area NFA2, and the third non-folding area NFA3.

Further, when the display device 100 is bent in the bending area BA, the first adhesive layer 187 and the heat dissipation sheet 190 may be disposed between the bottom plate 180 disposed in the second non-folding area NFA2 and the bottom plate 180 disposed in the third non-folding area NFA3.

Referring to FIGS. 3 and 4, the first adhesive layer 187 and the heat dissipation sheet 190 may not overlap the folding area FA of the display device 100.

Accordingly, the display device 100 may be folded or unfolded in the folding area FA without being interfered by the first adhesive layer 187 and the heat dissipation sheet 190.

The display device 100 according to one or more embodiments of the present disclosure includes a bottom plate 180 made of non-alkali glass to reduce the thickness of the display device 100, thereby reducing the weight of the display device 100.

Further, the bottom plate 180 is provided with a plurality of patterns 185 in the folding area FA of the display device 100 so that damage to the display device 100 may be reduced or prevented even when the display device 100 is repeatedly folded and unfolded.

In addition, the folding auxiliary layer 186 is disposed on the rear surface of the bottom plate 180 in the folding area FA to reduce or prevent wrinkles or damage that may occur in the folding area FA of the display device 100 and to block moisture and foreign substances flowing into the plurality of patterns 185.

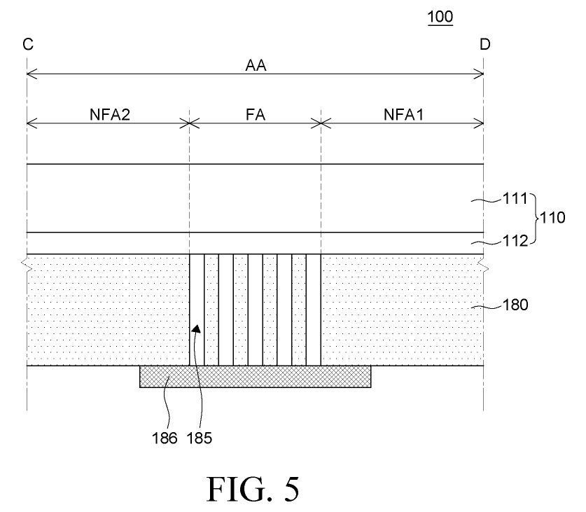

Next, the structure of the folding area FA of the display device 100 according to one or more embodiments of the present disclosure will be specifically reviewed with reference to FIG. 5.

FIG. 5 is a cross-sectional view taken along line C-D of FIG. 1.

Referring to FIG. 5, the display device 100 may include a display panel 110, a bottom plate 180, and a folding auxiliary layer 186.

The bottom plate 180 is disposed on the rear surface of the display panel 110 and may include a plurality of patterns 185 in the folding area FA.

The bottom plate 180 disposed on the rear surface of the substrate 112 may be formed of non-alkali glass.

The bottom plate 180 does not include an alkali metal so that the display element layer 111 on the substrate 112 may be formed in a state in which the bottom plate 180 is disposed on the rear surface of the substrate 112.

Specifically, a separate support substrate capable of supporting the substrate 112 is required to alleviate or prevent the substrate 112 from sagging during a process of forming the display element layer 111 on the substrate 112.

In order to form a plurality of light emitting devices, a plurality of transistors, and a plurality of link lines included in the display element layer 111, as an example, a deposition process of depositing a plurality of layers in a vacuum state may be utilized.

As the impurity content of the substrate 112 or the support substrate increases, it may be difficult to secure a vacuum state.

In particular, in the case of a glass substrate including an alkali metal, since the alkali metal acts as an impurity, it may be difficult to create a vacuum state.

Therefore, in order to create a vacuum state to a degree to which the display element layer 111 may be formed, a separate support substrate having a low impurity content was used under the substrate 112.

After the vacuum process, the support substrate may be separated from the bottom of the substrate 112 by a laser process (e.g., Laser Lift Off; LLO), and a separate back plate and a metal plate which support the substrate 112 below the substrate 112 may be attached to the bottom of the substrate 112 by means of a plurality of adhesive layers.

In particular, when the back plate attached to the rear surface of the substrate 112 is made of glass including an alkali metal, it is difficult to perform a vacuum process with the back plate attached to the rear surface of the substrate 112. Therefore, a separate support substrate capable of supporting the substrate 112 is required.

On the other hand, since the bottom plate 180 of the display device 100 according to one or more embodiments of the present disclosure is formed of non-alkaline glass, the impurity content of the bottom plate 180 is small, so that a vacuum process of forming the display element layer 111 on the substrate 112 in a state in which the bottom plate 180 is disposed on the rear surface of the substrate 112 is possible.

As an example, by disposing the bottom plate 180 made of non-alkaline glass on the rear surface of the substrate 112, it is possible to delete the step of disposing a separate support substrate and the step of separating the support substrate after the process of forming the display element layer 111, thereby simplifying the process.

Further, when the plurality of plates and the plurality of adhesive layers are disposed below the substrate 112, the thickness of the display device 100 is increased and the thickness thereof is increased so that the folding of the display device 100 may be difficult in the folding area FA.

On the other hand, in the display device 100 according to one or more embodiments of the present disclosure, only the bottom plate 180 and the folding auxiliary layer 186 are disposed on the rear surface of the substrate 112 in at least a part of the folding area FA, thereby facilitating the folding of the display device 100.

Further, in the folding area FA, the bottom plate 180 includes a plurality of patterns 185 and may have a shape of a plurality of patterns 185 that reduces or minimizes the influence of stress during folding and maintains rigidity even in repeated folding.

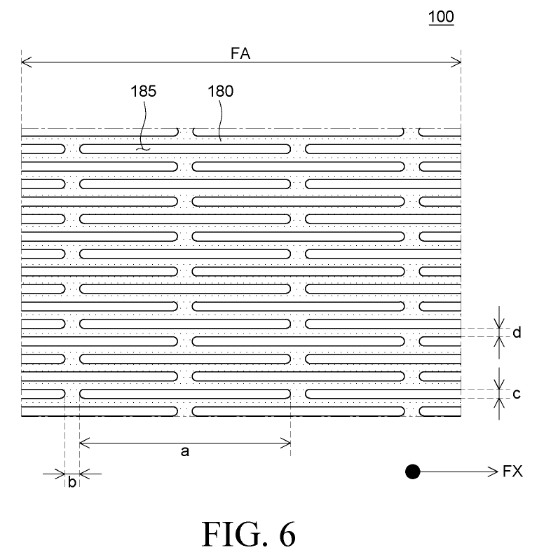

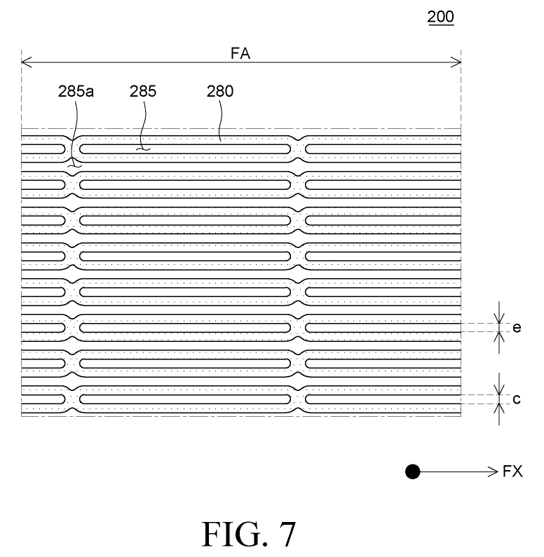

This will be reviewed with reference to FIGS. 6 and 7 as follows.

FIG. 6 is a view illustrating a plurality of patterns provided in the bottom plate in the folding area.

FIG. 7 is a view illustrating a plurality of patterns provided on a bottom plate in a folding area of a display device according to one or more other embodiments of the present disclosure.

First, referring to FIG. 6, the bottom plate 180 may include a plurality of patterns 185 in the folding area FA of the display device 100.

The plurality of patterns 185 may be hole patterns from which the bottom plate 180 is removed. The plurality of patterns 185 may be disposed to be spaced apart from each other to form a lattice pattern on a plane.

Specifically, the plurality of patterns 185 may have a long axis and a short axis, and the long axis of the plurality of patterns 185 may be in the same direction as the folding axis of the folding area FA.

Accordingly, the bottom plate 180 may be easily folded in the folding area FA.

As an example, the length (a) of the long axis of each of the plurality of patterns 185 may be 120 μm to 200 μm, without being limited thereto.

When the length a of the long axis of each of the plurality of patterns 185 is less than 120 μm, when the display device 100 is repeatedly folded, stress is concentrated in the folding area FA of the bottom plate 180, which may cause damage. In addition, when the length a of the long axis of each of the plurality of patterns 185 exceeds 200 μm, the plurality of patterns 185 may be visually recognized, thereby reducing the visibility of the display device 100.

The other pattern 185 adjacent to one pattern 185 may be disposed to be spaced apart from the one pattern 185 by a distance b in a direction in which the folding axis FX extends. Here, b may be formed to be 100 μm to 140 μm, without being limited thereto.

When a distance from the other pattern 185 adjacent to one pattern 185 to the one pattern 185 is less than 100 μm in a direction in which the folding axis FX extends, stress is concentrated in the folding area FA of the bottom plate 180 during the folding of the bottom plate 180 to be damaged. In addition, when a distance from the other pattern 185 adjacent to one pattern 185 to the one pattern 185 in a direction in which the folding axis FX extends exceeds 140 μm, the plurality of patterns 185 may be visually recognized, thereby reducing the visibility of the display device 100.

As an example, one pattern 185 may be disposed to be spaced apart from another adjacent pattern 185 in a direction (e.g., a folding direction) perpendicular to the direction in which the folding axis FX extends.

The length (c) of one pattern 185 with respect to a direction (e.g., a folding direction) perpendicular to the direction in which the folding axis FX extends, that is, the length (c) of the short axis may be longer than the distance (d) in which the plurality of patterns 185 are spaced apart from each other in the direction (e.g., the folding direction) perpendicular to the direction in which the folding axis FX extends.

As an example, the length c of the short axis of each of the plurality of patterns 185 may be 3.2 μm to 5.3 μm, and the distance d between the plurality of patterns 185 in a direction perpendicular to the direction in which the folding axis FX extends may be 0.24 μm to 0.4 μm. But the embodiments of the present application are not limited thereto.

When the length c of the short axis of each of the plurality of patterns 185 is less than 3.2 μm, the distance d between the plurality of patterns 185 in a direction perpendicular to the direction in which the folding axis FX extends exceeds 0.4 μm, such that the plurality of patterns 185 may be visually recognized by the viewer.

Further, when the length c of the short axis of each of the plurality of patterns 185 exceeds 5.3 μm, the process of forming the plurality of patterns 185 to be spaced apart from each other in a direction perpendicular to the direction in which the folding axis FX extends may be difficult, and the stress concentration phenomenon may occur in a partial area of the folding area FA of the bottom plate 180 during the folding.

However, the structure of the plurality of patterns 185 of the bottom plate 180 is not limited thereto.

For example, referring to FIG. 7, the bottom plate 280 of the display device 200 according to one or more other embodiments of the present disclosure may include an extension area 285a provided in at least one pattern 285.

The length of the extension area 285a in a direction perpendicular to the direction in which the folding axis FX extends may be greater than the length c of the short axis of the pattern 285.

The extension area 285a may serve to reduce the distance d between the plurality of patterns 285 spaced apart from each other in a direction perpendicular to a direction in which the folding axis FX extends in a part of the folding area FA.

Accordingly, it is possible to have an effect of reducing or preventing the plurality of patterns 285 from being visually recognized by the viewer.

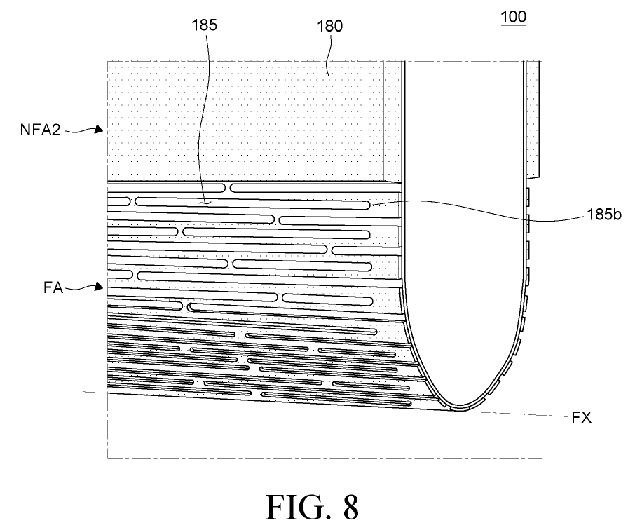

FIG. 8 is a view illustrating a state in which a bottom plate of the display device is folded around a folding axis according to one or more embodiments of the present disclosure.

Referring to FIG. 8, the bottom plate 180 may be folded around the folding axis FX in the folding area FA.

Since the stress concentration phenomenon does not occur even in repeated folding due to the plurality of patterns 185, the bottom plate 180 may be easily folded.

The bottom plate 180 may include an edge area 185b of a plurality of patterns 185 disposed in the folding area FA.

The edge area 185b may include a boundary between the bottom plate 180 and a plurality of patterns 185 that are hole patterns.

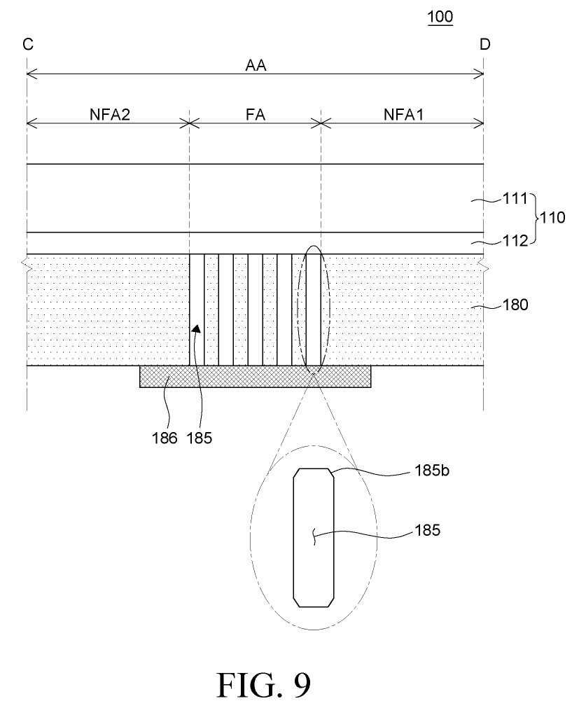

FIG. 9 is a view illustrating a shape of edges of a plurality of patterns in an edge area of a bottom plate in a folding area of a bottom plate of a display device according to one or more embodiments of the present disclosure.

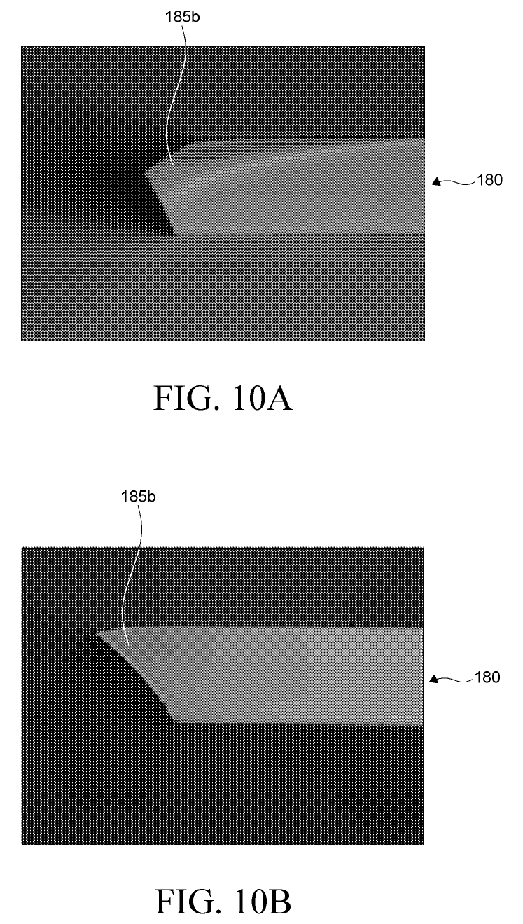

FIGS. 10A and 10B are images of the shape of the edge area of the bottom plate.

Referring to FIGS. 9, 10A, and 10B, the bottom plate 180 may include an edge area 185b.

At least a portion of the edge area 185b disposed to be adjacent to the plurality of patterns 185 in the folding area FA may have a tapered shape.

The plurality of patterns 185 may be formed by an etching process of the bottom plate 180, and in a process of forming the plurality of patterns 185, a part of the edge area 185b may be formed to have a tapered shape. Accordingly, it is possible to reduce or prevent stress from being concentrated on the boundary between the plurality of patterns 185 and the edge area 185b during the folding of the bottom plate 180.

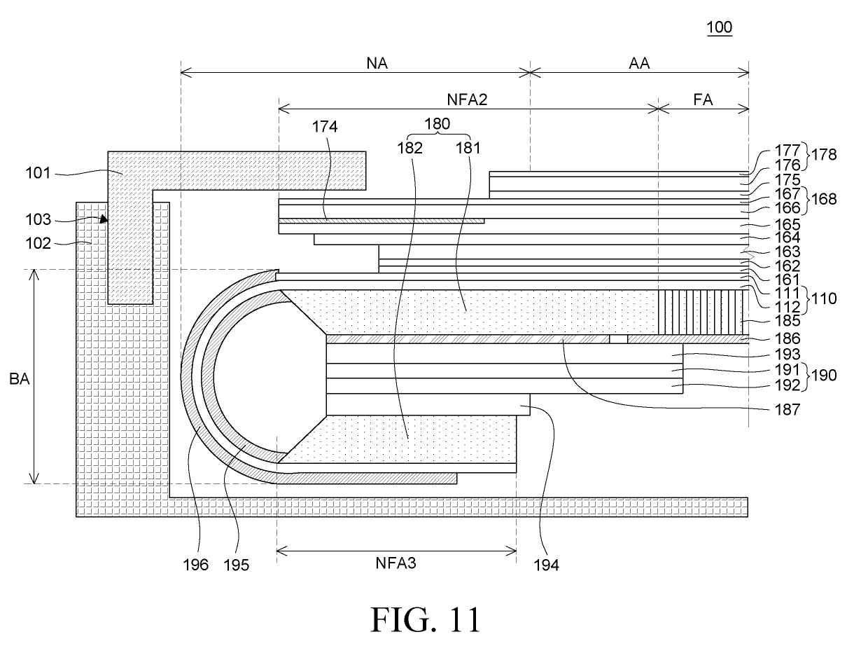

FIG. 11 is a cross-sectional view of a display device according to one or more embodiments of the present disclosure.

The cross-sectional view of FIG. 11 illustrates a state in which the display panel 110 is bent in the bending area BA of the display device 100.

Referring to FIG. 11, the display device 100 may include a display panel 110, a cover member 164, a bottom plate 180, a folding auxiliary layer 186, a heat dissipation sheet 190, a top case 101, and a bottom case 102. Embodiments are not limited thereto. As an example, at least one of the above-mentioned components could be omitted, or at least one additional component may be further included.

Specifically, the bottom plate 180, the folding auxiliary layer 186, the first adhesive layer 187, a digitizer 193, the heat dissipation sheet 190, and the second adhesive layer 194 may be disposed on the rear surface of the display panel 110.

In the folding area FA and the second non-folding area NFA2 of the display device 100, the bottom plate 180 may be disposed on the rear surface of the display panel 110.

The bottom plate 180 may include a first bottom plate 181 and a second bottom plate 182 which are disposed to be spaced apart from each other.

The first bottom plate 181 may be disposed on the rear surface of the display panel 110 in the folding area FA and the second non-folding area NFA2. In addition, the first bottom plate 181 may overlap the entire display area AA and may overlap a part of the non-display area NA.

In a state in which the display panel 110 is bent, the second bottom plate 182 may be disposed below the first bottom plate 181. The second bottom plate 182 may be disposed in the third non-folding NFA3 area and may be disposed in a part of the non-display area NA.

In the state in which the display panel 110 is bent, the folding auxiliary layer 186 and the first adhesive layer 187 may be disposed on the rear surface of the first bottom plate 181.

The folding auxiliary layer 186 may overlap the entire folding area FA and may overlap a part of the second non-folding area NFA2. The folding auxiliary layer 186 may be disposed in a part of the display area AA of the display device 100.

[The first adhesive layer 187 may not be disposed in the folding area FA, and may be disposed in at least a portion of the second non-folding area NFA2. The first adhesive layer 187 may be disposed to be spaced apart from the folding auxiliary layer 186, but is not limited thereto. As an example, the heat dissipation sheet 190 may overlap a gap between the first adhesive layer 187 and the folding auxiliary layer 186, but is not limited thereto. As an example, the heat dissipation sheet 190 may overlap the entire first adhesive layer 187a, the gap between the first adhesive layer 187 and the folding auxiliary layer 186 and a part of the folding auxiliary layer 186, but is not limited thereto.

In addition, as an example, the thickness of the first adhesive layer 187 may be thicker than the thickness of the folding auxiliary layer 186. Accordingly, the digitizer 193 and the folding auxiliary layer 186 attached to the rear surface of the first bottom plate 181 may be at least partially prevented from interfering with each other.

The digitizer 193 is an input device that converts movements of a pen or a finger into a digital signal. As an example, the digitizer 193 may be omitted depending on the design.

The heat dissipation sheet 190 may be disposed on the rear surface of the digitizer 193. The heat dissipation sheet 190 may include a first heat dissipation sheet 191 and a second heat dissipation sheet 192 disposed on a rear surface of the first heat dissipation sheet 191, without being limited thereto.

The first heat dissipation sheet 191 and the second heat dissipation sheet 192 may include different materials. For example, the first heat dissipation sheet 191 may include graphite, and the second heat dissipation sheet may include copper (Cu), but is not limited thereto.

A second adhesive layer 194 may be disposed on the rear surface of the second heat dissipation sheet 192. The second adhesive layer 194 may be a foam-tape, but is not limited thereto.

Each of the digitizer 193 and the heat dissipation sheet 190 may overlap a portion of the folding auxiliary layer 186. However, the present disclosure is not limited thereto, and each of the digitizer 193 and the heat dissipation sheet 190 may not overlap the folding auxiliary layer 186. Accordingly, it is possible to reduce or prevent the digitizer 193 and the heat dissipation sheet 190 from interfering with the folding of the display device 100.

In a state in which the display panel 110 is bent, the second bottom plate 182, the substrate 112 of the display panel 110, and a second micro coating layer 196 may be sequentially disposed on the rear surface of the second adhesive layer 194.

In the bending area BA of the display device 100, as an example, the display device 100 may include a substrate 112, a first micro coating layer 195 disposed on a rear surface of the substrate 112, and the second micro coating layer 196 disposed on a top surface of the substrate 112.

Although not illustrated in FIG. 11, a plurality of link lines may be further disposed on the substrate 112 in the bending area BA.

The second micro coating layer 196 may serve to reduce or prevent a plurality of link lines disposed on the substrate 112 from being damaged due to concentration of stress in the bending state and to adjust the neutral plane of the bending area BA.

A plurality of adhesive layers, a cover member 164, and a plurality of hard coating assemblies may be disposed on the top surface of the display panel 110, without being limited thereto.

Specifically, the first adhesive member 161 may be disposed on the top surface of the display panel 110. The first adhesive member 161 may have a low light absorption rate for light of the plurality of light emitting elements disposed on the display panel 110. For example, the first adhesive member 161 may be an optically cleared adhesive (OCA), but is not limited thereto.

The polarization layer 162 may be disposed on the first adhesive member 161.

The second adhesive member 163 may be disposed on the polarization layer 162. The second adhesive member 163 may include the same material as the first adhesive member 161, but is not limited thereto.

A cover member 164 may be disposed on the second adhesive member 163. The cover member 164 protects the display panel 110 from an external impact and transmits light emitted from the display panel 110 so that an image displayed on the display panel 110 is visible from the outside.

The cover member 164 may be disposed closer to the bending area BA of the display device 100 than each of the first adhesive member 161, the polarization layer 162, and the second adhesive member 163. Accordingly, the cover member 164 may protect the display panel 110 and the polarization layer 162.

A third adhesive member 165 may be disposed on the cover member 164. The third adhesive member 165 may include the same material as the first adhesive member 161, but is not limited thereto.

A light shielding layer 174 may be disposed on a part of the top surface of the third adhesive member 165. The light shielding layer 174 may serve to block various circuits and link lines disposed in the non-display area NA of the display panel 110 and various structures disposed in the non-display area NA of the display panel 110 from being visually recognized by a user.

A plurality of hard coating assemblies may be disposed on the third adhesive member 165 and the light shielding layer 174.

The hard coating assembly may include a first hard coating assembly 168 and a second hard coating assembly 178 disposed on the first hard coating assembly 168.

The first hard coating assembly 168 may include a first base layer 166 disposed on the third adhesive member 165 and the light shielding layer 174, and a first hard coating layer 167 disposed on the first base layer 166.

The second hard coating assembly 178 may include a second base layer 176 disposed on the first hard coating layer 167 and a second hard coating layer 177 disposed on the second base layer 176.

A fourth adhesive member 175 may be disposed between the first hard coating assembly 168 and the second hard coating assembly 178, and the first hard coating layer 167 and the second base layer 176 may be bonded to each other through the fourth adhesive member 175.

Further, as an example, the display device 100 may include a top case 101 and a bottom case 102, without being limited thereto.

As an example, a partial area of the top case 101 may be inserted into the fastening groove 103 of the bottom case 102 located on the side surface of the display device 100 to be fastened to the bottom case 102, without being limited thereto.

The top case 101 may be disposed to surround a part of the top surface and a part of the side surface of the display device 100.

The bottom case 102 may be disposed to surround a part of the side surface of the display device 100 and the rear surface of the display device 100.

The top case 101 may overlap a part of the display panel 110 disposed in the non-display area NA of the display device 100, a part of the cover member 164, and a part of each of the first hard coating assemblies 168.

Further, the top case 101 is disposed to be spaced apart from the second hard coating assembly 178 with respect to a direction perpendicular to a direction in which the cover member 164 is stacked on the display panel 110, thereby reducing or preventing the top case 101 and the second hard coating assembly 178 from interfering with each other.

In the folding area FA of the display device 100, a first adhesive member 161, the polarization layer 162, a second adhesive member 163, a cover member 164, a third adhesive member 165, a first base layer 166, a first hard coating layer 167, a fourth adhesive member 175, a second base layer 176, and a second hard coating layer 177 may be disposed.

As an example, each of the first adhesive member 161, the polarization layer 162, the second adhesive member 163, the cover member 164, the third adhesive member 165, the first base layer 166, the first hard coating layer 167, the fourth adhesive member 175, the second base layer 176, and the second hard coating layer 177 has a thickness of 5 μm to 65 μm, so that folding may be easily performed in the folding area FA, but is not limited thereto. As an example, at least one of the first adhesive member 161, the polarization layer 162, the second adhesive member 163, the cover member 164, the third adhesive member 165, the first base layer 166, the first hard coating layer 167, the fourth adhesive member 175, the second base layer 176, and the second hard coating layer 177 may be omitted at least in the folding area FA, without being limited thereto.

The area of the folding area FA of the display device 100 may be disposed in the display area AA, and the plurality of emission areas disposed in the folding area FA may overlap the plurality of patterns 185 and the folding auxiliary layer 186.

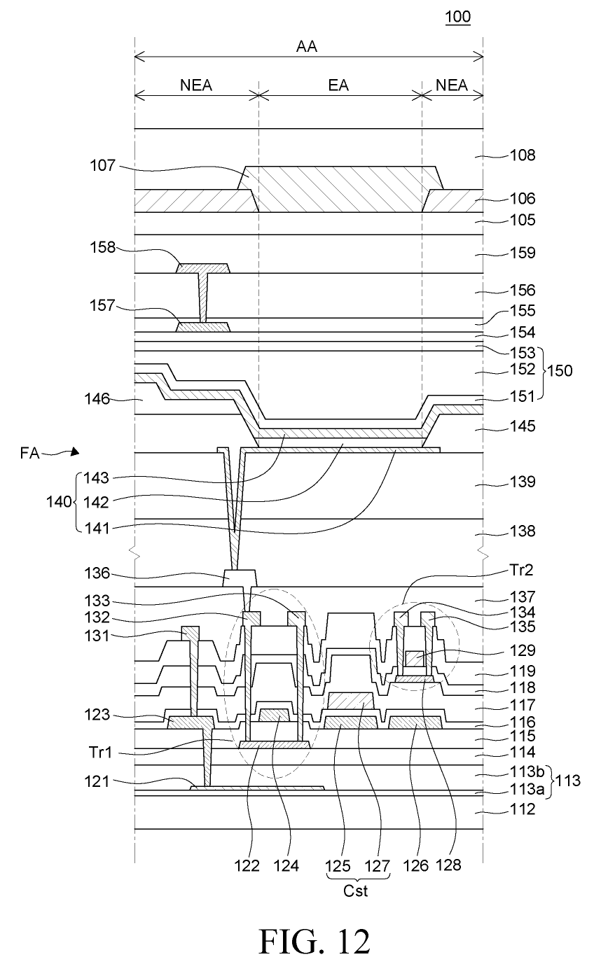

FIG. 12 is a cross-sectional view illustrating a part of a display area located in a folding area of a display device according to one or more embodiments of the present disclosure.

Referring to FIG. 12, a plurality of transistors Tr1 and Tr2 and a light emitting element 140 disposed on the substrate 112 may be included, and a bottom plate 180 and a folding auxiliary layer 186 disposed on a rear surface of the substrate 112 may be included.

Specifically, the multi-buffer layer 113 may be disposed on the substrate 112.

The multi-buffer layer 113 may include a first multi-buffer layer 113a disposed on the substrate 112 and a second multi-buffer layer 113b disposed on the first multi-buffer layer 113a, without being limited thereto.

A first metal layer 121 having a single film or a multi-filmed structure may be disposed between the first multi-buffer layer 113a and the second multi-buffer layer 113b. The first metal layer 121 may serve as a light shielding film LS that blocks light. As an example, the first metal layer 121 may be omitted depending on the design.

The active buffer layer 114 may be disposed on the second multi-buffer layer 113b.

The first transistor Tr1 and the second transistor Tr2 may be disposed on the active buffer layer 114.

The first transistor Tr1 may include a first active layer 122, a first gate electrode 124, a first source electrode 132, and a first drain electrode 133.

The second transistor Tr2 may include a second active layer 128, a second gate electrode 129, a second source electrode 134, and a second drain electrode 135.

The first transistor Tr1 may be a driving transistor, and the second transistor Tr2 may be a sensing transistor, but is not limited thereto.

Specifically, the first active layer 122 may be disposed on the active buffer layer 114. The first active layer 122 may be disposed to overlap the first metal layer 121.

A first gate insulating layer 115 may be disposed on the first active layer 122. The first gate insulating layer 115 may be disposed while covering the first active layer 122.

The second metal layer 123, the first gate electrode 124, the first storage capacitor electrode 125, and the third metal layer 126 may be disposed on the first gate insulating layer 115. The second metal layer 123, the first gate electrode 124, the first storage capacitor electrode 125, and the third metal layer 126 may be disposed on the same layer and formed of the same material, without being limited thereto. Accordingly, the process of forming the display panel 110 may be simplified.

The second metal layer 123 may be in contact with and electrically connected to the first metal layer 121 through contact holes provided in the first gate insulating layer 115, the active buffer layer 114, and the second multi-buffer layer 113b. But embodiments are not limited thereto. As an example, the first metal layer 121 may be floated, without being connected to any electrode or metal layer.

The first gate electrode 124 may be disposed to overlap a portion of the first active layer 122.

The third metal layer 126 may be disposed to be spaced apart from the first storage capacitor electrode 125. Here, the third metal layer 126 may be a light shielding film that blocks light. As an example, the third metal layer 126 may be floated or may be connected to an electrode or a metal layer. As an example, the third metal layer 126 may be omitted depending on the design.

A first interlayer insulating layer 116 may be disposed on the second metal layer 123, the first gate electrode 124, the first storage capacitor electrode 125, and the third metal layer 126.

The second storage capacitor electrode 127 may be disposed on the first interlayer insulating layer 116. The second storage capacitor electrode 127 may overlap the first storage capacitor electrode 125 to form a storage capacitor Cst.

A second interlayer insulating layer 117 may be disposed on the second storage capacitor electrode 127.

The second active layer 128 may be disposed on the second interlayer insulating layer 117. The second active layer 128 may be disposed to overlap the third metal layer 126.

Each of the first active layer 122 and the second active layer 128 may be formed of an oxide semiconductor or amorphous silicon (a-Si), polycrystalline silicon (poly-Si), a compound semiconductor, or an organic semiconductor.

A second gate insulating layer 118 may be disposed on the second active layer 128.

The second gate electrode 129 may be disposed on the second gate insulating layer 118. The second gate electrode 129 may be disposed to overlap a portion of the second active layer 128.

A third interlayer insulating layer 119 may be disposed on the second gate electrode 129.

The fourth metal layer 131, the first source electrode 132, the first drain electrode 133, the second source electrode 134, and the second drain electrode 135 may be disposed on the third interlayer insulating layer 119. The fourth metal layer 131, the first source electrode 132, the first drain electrode 133, the second source electrode 134, and the second drain electrode 135 may be disposed on the same layer and formed of the same material, without being limited thereto. Accordingly, the process of forming the display panel 110 may be simplified.

The fourth metal layer 131 may be electrically connected by being in contact with the second metal layer through contact holes provided in the third interlayer insulating layer 119, the second gate insulating layer 118, the second interlayer insulating layer 117, and the first interlayer insulating layer 116.

Each of the first source electrode 132 and the first drain electrode 133 may be electrically connected to one end and the other end of the first active layer 122 through contact holes provided in the third interlayer insulating layer 119, the second gate insulating layer 118, the second interlayer insulating layer 117, the first interlayer insulating layer 116, and the first gate insulating layer 115.

A portion of the first active layer 122 that overlaps the first gate electrode 124 is a channel area. The first source electrode 132 may be connected to one end of the channel area of the first active layer 122, and the first drain electrode 133 may be connected to the other end of the channel area of the first active layer 122.

Each of the second source electrode 134 and the second drain electrode 135 may be electrically connected to one end and the other end of the second active layer 128 through contact holes provided in the third interlayer insulating layer 119 and the second gate insulating layer 118.

A portion of the second active layer 128 overlapping the second gate electrode 129 is a channel area. The second source electrode 134 may be connected to one end of the channel area of the second active layer 128, and the second drain electrode 135 may be connected to the other end of the channel area of the second active layer 128.

A first planarization layer 137 may be disposed on the fourth metal layer 131, the first source electrode 132, the first drain electrode 133, the second source electrode 134, and the second drain electrode 135.

The connection electrode 136 may be disposed on the first planarization layer 137.

The connection electrode 136 may be electrically connected by being in contact with the first source electrode 132 through a contact hole provided in the first planarization layer 137.

As an example, a second planarization layer 138 and a third planarization layer 139 may be sequentially disposed on the connection electrode 136, without being limited thereto. As an example, at least one of the second planarization layer 138 and the third planarization layer 139 may be omitted depending on the design.

The second planarization layer 138 and the third planarization layer 139 may serve to planarize a top surface of the substrate 112 on which the plurality of transistors, the plurality of metal layers, and the plurality of electrodes are disposed.

The light emitting element 140 may be disposed on the third planarization layer 139.

The light emitting element 140 may include a first electrode 141, an organic layer 142, and a second electrode 143.

The first electrode 141 may be an anode electrode of the light emitting element 140, and the second electrode 143 may be a cathode electrode of the light emitting element 140, but is not limited thereto. For example, the first electrode 141 may be a cathode electrode, and the second electrode 143 may be an anode electrode.

The first electrode 141 may be disposed on a part of a top surface of the third planarization layer 139.

The first electrode 141 may be electrically connected to the connection electrode 136 through a contact hole provided in the third planarization layer 139 and the second planarization layer 138.

The bank 145 may be disposed on a part of the top surface of the first electrode 141 and the third planarization layer 139.

The bank 145 may include a black-colored organic material to improve reflection visibility due to external light, but is not limited thereto.

The bank 145 may define an emission area EA and a non-emission area NEA of a sub pixel disposed in the display area AA.

Specifically, the bank 145 may include a bank hole (or an opening of the bank) which exposes a part of a top surface of the first electrode 141, and an area which overlaps the bank hole may be the emission area EA of the sub pixel.

Further, an area of the sub pixel in which the bank 145 is disposed may be the non-emission area NEA.

A spacer 146 may be disposed on a part of a top surface of the bank 145. The spacer 146 may serve to reduce or prevent the encapsulation layer 150 disposed on the second electrode 143 of the light emitting element 140 from being lifted by the folding of the display device 100.

The organic layer 142 of the light emitting element 140 may be disposed on the top surface of the first electrode 141 exposed due to the bank 145. Accordingly, the organic layer 142 may be in contact with the top surface of the first electrode 141 in the hole of the bank 145.

FIG. 12 illustrates a structure in which the organic layer 142 is a single layer. However, the present disclosure is not limited thereto. The organic layer 142 may have a multilayer structure including at least one emission layer.

The second electrode 143 of the light emitting element 140 may be disposed on the organic layer 142, the bank 145, and the spacer 146.

The first electrode 141 of the light emitting element 140 may include a reflective electrode, and the second electrode 143 may include an electrode or a transflective electrode made of a transparent conductive material, but is not limited thereto.

The encapsulation layer 150 may be disposed on the second electrode 143.

The encapsulation layer 150 may have a single layer structure or a multi-layer structure. For example, the encapsulation layer 150 may include a first encapsulation layer (or film) 151, a second encapsulation layer (or film) 152, and a third encapsulation layer (or film) 153.

The first encapsulation film 151 and the third encapsulation film 153 may be inorganic films, and the second encapsulation film 152 may be an organic film. Among the first encapsulation film 151, the second encapsulation film 152, and the third encapsulation film 153, the second encapsulation film 152, which is an organic film, is the thickest and may serve as a planarization film.

A first touch buffer layer 154 may be disposed on the encapsulation layer 150.

The first touch electrode 157 may be disposed on the first touch buffer layer 154.

A second touch buffer layer 155 may be disposed on the first touch electrode 157. FIG. 11 illustrates a structure in which the second touch buffer layer 155 is a single film, but is not limited thereto, and the second touch buffer layer 155 may have a multi-filmed structure. In this case, the inorganic film or the organic film may be alternately disposed, without being limited thereto.

A touch interlayer insulating layer 156 may be disposed on the second touch buffer layer 155. The touch interlayer insulating layer 156 may include an organic material, but is not limited thereto.

The second touch electrode 158 may be disposed on the touch interlayer insulating layer 156. The second touch electrode 158 may be electrically connected to the first touch electrode 157 through a contact hole formed in the second touch buffer layer 155 and the touch interlayer insulating layer 156. Each of the first touch electrode 157 and the second touch electrode 158 may be disposed in the non-emission area NEA of the display area AA.

The plurality of patterns and the folding auxiliary layer of the bottom plate may be disposed in each of the emission area EA and the non-emission area NEA of the folding area FA. Further, in the non-emission area NEA of the folding area FA, each of the first touch electrode 157 and the second touch electrode 158 may overlap the plurality of patterns of the bottom plate and the folding auxiliary layer.

An organic material layer 159 may be disposed on the second touch electrode 158.

The color filter buffer layer 105 may be disposed on the organic material layer 159.

The black matrix 106 and the color filter 107 may be disposed on the color filter buffer layer 105.

The black matrix 106 may be disposed in the non-emission area NEA of the display area AA. In addition, the color filter 107 may be disposed in the emission area EA of the display area AA, and may extend to a part of the non-emission area NEA.

Further, even though it is not illustrated in FIG. 12, the black matrix 106 and the color filter 107 in the display area AA of the folding area FA may overlap the plurality of patterns 185 of the bottom plate 180.

Further, even though in FIG. 12, the display area AA disposed in the folding area FA is illustrated as an example, the structure of the display device 100 according to one or more embodiments of the present disclosure is not limited thereto. A structure of the display area AA of each of the first non-folding area NEA1 and the second non-folding area NEA2 may be the same as that of FIG. 12.

For example, each of the first non-folding area NEA1 and the second non-folding area NEA2 includes an emission area EA and a non-emission area NEA, and each of the first touch electrode 157 and the second touch electrode 158 may overlap the non-emission area NEA. In addition, each of the first touch electrode 157 and the second touch electrode 158 may overlap a part of the folding auxiliary layer.

According to one or more embodiments of the present disclosure, a display device includes a display panel including a folding area, a first non-folding area, and a second non-folding area, a bottom plate disposed on a rear surface of the display panel, and a folding auxiliary layer disposed on a rear surface of the bottom plate, the bottom plate includes a plurality of patterns overlapping the folding area, the folding auxiliary layer overlaps the entire folding area, and overlaps a part of each of the first non-folding area and the second non-folding area disposed with the folding area therebetween.

According to one or more other embodiments of the present disclosure, the display panel includes a substrate disposed on the bottom plate, and the substrate may be a single layer.

According to yet one or more other embodiments of the present disclosure, edges of the plurality of patterns may have a tapered shape.

According to yet one or more other embodiments of the present disclosure, the display panel may further include a bending area and a third non-folding area, and the bending area may be disposed between the second non-folding area and the third non-folding area.

According to yet one or more other embodiments of the present disclosure, a part of each of the folding area, the first non-folding area, and the second non-folding area may include a display area.

According to yet one or more other embodiments of the present disclosure, the plurality of patterns may be disposed to be spaced apart from each other in the same direction as the direction in which the folding axis of the folding area extends and in a direction perpendicular to the direction in which the folding axis extends.

According to yet one or more other embodiments of the present disclosure, each of the plurality of patterns may be spaced apart from each other by 100 μm to 140 μm in the same direction as the direction in which the folding axis of the folding area extends.

According to yet one or more other embodiments of the present disclosure, the folding area includes a emission area and a non-emission area, and the plurality of patterns and the folding auxiliary layer may overlap the emission area and the non-emission area of the folding area, respectively.

According to yet one or more other embodiments of the present disclosure, the display device may further include a plurality of first touch electrodes disposed in a folding area of the display panel. At least a part of the plurality of patterns and the folding auxiliary layer may overlap the plurality of first touch electrodes.

According to yet one or more other embodiments of the present disclosure, each of the first non-folding area and the second non-folding area may include a emission area and a non-emission area, and the folding auxiliary layer may overlap a part of the emission area of the first non-folding area and the second non-folding area and a part of the non-emission area.

According to yet one or more other embodiments of the present disclosure, the display device may further include a plurality of second touch electrodes disposed in each of the first non-folding area and the second non-folding area of the display panel, and the folding auxiliary layer may overlap a part of the plurality of second touch electrodes.

According to yet one or more other embodiments of the present disclosure, the bottom plate may be made of non-alkali glass, which is a single layer.

According to yet one or more other embodiments of the present disclosure, the display device may further comprise a cover member disposed on the display panel, the cover member may be a glass including an alkali metal.

According to yet one or more other embodiments of the present disclosure, the display panel may further include a third non-folding area spaced apart from the second non-folding area, the bottom plate may include a first bottom plate and a second bottom plate spaced apart from each other, the first bottom plate may overlap the folding area, the first non-folding area, and the second non-folding area, and the second bottom plate may overlap the third non-folding area.

According to yet one or more other embodiments of the present disclosure, a micro coating layer may be disposed between the first bottom plate and the second bottom plate.

Although embodiments of the present disclosure have been described in detail with reference to the accompanying drawings, the present disclosure is not limited thereto and may be embodied in various forms without departing from the technical concept of the present disclosure. Therefore, embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all embodiments and do not limit the present disclosure.

What is claimed is:

1. A display device, comprising:
a display panel including a folding area, and a first non-folding area and a second non-folding area disposed with the folding area between the first non-folding area and the second non-folding area;
a bottom plate disposed on a rear surface of the display panel; and
a folding auxiliary layer disposed on a rear surface of the bottom plate,
wherein the bottom plate includes a plurality of patterns overlapping the folding area,
wherein the folding auxiliary layer overlaps an entirety of the folding area, and
wherein the folding auxiliary layer overlaps portions of each of the first non-folding area and the second non-folding area.

2. The display device according to claim 1, wherein the display panel includes a substrate disposed on the bottom plate, and
wherein the substrate is a single layer.

3. The display device according to claim 1, wherein edges of the plurality of patterns adjacent to the first non-folding area or the second non-folding area are tapered.

4. The display device according to claim 1, further comprising:
a bending area and a third non-folding area,
wherein the bending area is disposed between the second non-folding area and the third non-folding area.

5. The display device according to claim 4, wherein the bending area is spaced apart from the folding area in a folding direction,
wherein a display area is disposed in the folding area and is not disposed in the bending area, and
wherein a radius of a curvature of the folding area in a folded state is smaller than a radius of a curvature of the bending area in a bent state.

6. The display device according to claim 1, wherein a part of each of the folding area, the first non-folding area, and the second non-folding area includes a display area.

7. The display device according to claim 1, wherein the plurality of patterns is spaced apart from each other both in an axis direction parallel to a folding axis of the folding area and in a folding direction perpendicular to the folding axis.

8. The display device according to claim 7, wherein the plurality of patterns is spaced apart from each other by 100 μm to 140 μm in the axis direction.

9. The display device according to claim 7, wherein the plurality of patterns is a plurality of hole patterns from which the bottom plate is removed.

10. The display device according to claim 9, wherein each of the plurality of patterns has a long axis parallel to the axis direction and a short axis parallel to the folding direction.

11. The display device according to claim 10, wherein a length of the short axis is longer than a distance by which patterns of the plurality of patterns are spaced apart from each other in the folding direction.

12. The display device according to claim 1, wherein the folding area includes an emission area and a non-emission area, and
wherein the plurality of patterns and the folding auxiliary layer overlap each of the emission area and the non-emission area of the folding area.

13. The display device according to claim 1, further comprising:
a plurality of first touch electrodes disposed in the folding area of the display panel,
wherein at least a part of the plurality of patterns and the folding auxiliary layer overlap the plurality of first touch electrodes.

14. The display device according to claim 1, wherein each of the first non-folding area and the second non-folding area includes an emission area and a non-emission area, and
wherein the folding auxiliary layer overlaps a part of the emission area and a part of the non-emission area of the first non-folding area and the second non-folding area.

15. The display device according to claim 14, further comprising:
a plurality of second touch electrodes respectively disposed in the first non-folding area and the second non-folding area of the display panel,
wherein the folding auxiliary layer overlaps a part of the plurality of second touch electrodes.

16. The display device according to claim 1, wherein the bottom plate is formed of a non-alkali glass which is a single layer.

17. The display device of claim 16, further comprising:
a cover member disposed on the display panel,
wherein the cover member is a glass including an alkali metal.

18. The display device of claim 16, wherein the display panel includes a substrate disposed on the bottom plate and a display element layer disposed on the substrate, and
wherein the display element layer is formed on the substrate in a state in which the bottom plate is disposed on a rear surface of the substrate.

19. The display device according to claim 1, wherein the display panel further includes a third non-folding area spaced apart from the second non-folding area,
wherein the bottom plate includes a first bottom plate and a second bottom plate disposed to be spaced apart from each other,
wherein the first bottom plate overlaps the folding area, the first non-folding area, and the second non-folding area, and
wherein the second bottom plate overlaps the third non-folding area.

20. The display device of claim 19, wherein a micro coating layer is disposed between the first bottom plate and the second bottom plate.
